(19) United States
(12) Patent Application Publication
(10) Pub. No.: US 2025/0081357 A1
(43) Pub. Date: Mar. 6, 2025

(54) INTERPOSER FOR TROUBLESHOOTING A BALL GRID ARRAY (BGA) DEVICE AND COUPLING THE BGA DEVICE TO A PRINTED CIRCUIT BOARD WITH LIMITED HEAT EXPOSURE

(71) Applicant: Western Digital Technologies, Inc., San Jose, CA (US)

(72) Inventors: Nadav Tsur, Bet Herut Hatamar (IL); Igor Akerman, Ganey-Tikva (IL); Yair Sommer, Even-Yehuda (IL); Avi Zeev Shani, Petach Tikva (IL)

(21) Appl. No.: 18/238,952

(22) Filed: Aug. 28, 2023

(51) Int. Cl. H05K 3/34; H05K 1/11

(52) U.S. Cl. CPC H05K 3/3436; H05K 1/111; H05K 1/118; H05K 2201/10378; H05K 2201/10734

(57) ABSTRACT

Interposers for coupling a ball grid array (BGA) device to a printed circuit board (PCB) and related methods are provided. One such method involves aligning a first array of conductive rings on a flexible substrate of the interposer with ball pads of a BGA device, coupling the first conductive rings to the ball pads, aligning a second array of conductive rings on the flexible substrate with connectors of a first PCB including an array of connectors, and coupling the second conductive rings to the array of connectors of the first PCB. One such interposer assembly includes a flexible substrate, a first array of conductive rings on the flexible substrate, wherein the first conductive rings is attached to an array of ball pads of a BGA device, a second array of conductive rings on the flexible substrate, and conductive traces connecting the first and second conductive rings.

### FIELD

The subject matter described herein relates to tools for troubleshooting integrated circuit devices. More particularly, the subject matter relates, in some examples, to interposers for troubleshooting a ball grid array (BGA) device and coupling the BGA device to a printed circuit board with limited heat exposure.

### INTRODUCTION

A ball grid array (BGA) is a type of surface-mount packaging, used for example. for all sorts of integrated circuit (IC) devices including components of data storage devices such as solid state devices (SSDs). The ball grid array package generally includes an array of metal balls (e.g., solder balls) disposed on one side of the IC device and used to mount and electrically couple the IC device (e.g., BGA device) to a printed circuit board. The ball grid array provides a functional connection between the BGA device and the printed circuit board.

SSDs that incorporate non-volatile memories (NVMs), volatile memories, processors, and other integrated circuitry can make use of BGA packages to connect to PCBs (e.g., for select integrated circuit components having a high pin count, a need for heat conduction, and/or a need for low inductance leads). The SSDs may require testing and failure analysis, both in manufacturing and in customer applications. As used herein, a device that requires testing and failure analysis may be referred to as a “device under test.” Depending on the context, a device under test may refer to a BGA device, a printed circuit board (PCB), a printed circuit board assembly (PCBA), or the like, that requires testing.

In order to test and analyze a device under test (e.g., such as an SSD implemented with an integrated circuit chip in a BGA package), in some circumstances it must be removed from a PCB. However, removal of the BGA chip from the PCB often results in damage to the ball grid array of the BGA chip/device. In order to connect, or reconnect the device under test to the PCB, it is customary to use a rework solder machine. The rework solder machine evenly heats the BGA device (e.g., to dislodge solder) so that it may be connected or reconnected to the PCB. This process requires specialized knowledge and tooling (e.g., use/availability of the rework solder station) not always available to a technician, particularly where the technician is dispatched to a remote location. Likewise, use of the rework solder station may expose the BGA device to heat levels that can alter the associated circuit components, defeating the purpose of the test in some instances. Removal of the BGA chip from the PCB can also be accomplished using mechanical means (e.g., grinding). Due to the damage to the BGA chip and solder balls, a re-balling process is required to reattach solder balls. However, the re-balling process exposes the BGA device to heat at levels that can alter the associated circuit components, again defeating the purpose of the test in some instances.

### SUMMARY

The following presents a simplified summary of some aspects of the disclosure to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present various concepts of some aspects of the disclosure in a simplified form as a prelude to the more detailed description that is presented later.

One aspect of the disclosure provides a method for connecting an interposer. comprising: aligning a first array of conductive rings on a flexible substrate of the interposer with ball pads of a ball grid array device; coupling the first array of conductive rings to the ball pads of the ball grid array device; aligning a second array of conductive rings on the flexible substrate of the interposer with connectors of a first printed circuit board comprising an array of connectors for coupling to the ball grid array device; and coupling the second array of conductive rings to the array of connectors of the first printed circuit board.

Another aspect of the disclosure provides an interposer assembly, comprising: a flexible substrate; a first array of conductive rings formed in a first pattern on the flexible substrate, wherein the first array of conductive rings is attached to an array of ball pads of a ball grid array device such that at least one conductive ring of the first array of conductive rings is attached to one ball pad of the array of ball pads; a second array of conductive rings formed in a second pattern on the flexible substrate; and a plurality of conductive traces connecting conductive rings of the first array to conductive rings of the second array.

Another aspect of the disclosure provides a method for connecting an interposer comprising a flexible substrate comprising first and second arrays of conductive rings, the method comprising: aligning the second array of conductive rings on the flexible substrate of the interposer with connectors of a first printed circuit board comprising an array of connectors for coupling to a ball grid array device; coupling the second array of conductive rings to the array of connectors of the first printed circuit board; aligning the first array of conductive rings on the flexible substrate of the interposer with ball pads of a ball grid array device; and coupling the first array of conductive rings to the ball pads of the ball grid array device.

These and other aspects of the disclosure will become more fully understood upon a review of the detailed description, which follows. Other aspects, features, and implementations of the disclosure will become apparent to those of ordinary skill in the art, upon reviewing the following description of specific implementations of the disclosure in conjunction with the accompanying figures. While features of the disclosure may be discussed relative to certain implementations and figures below, all implementations of the disclosure can include one or more of the advantageous features discussed herein. In other words, while one or more implementations may be discussed as having certain advantageous features, one or more of such features may also be used in accordance with the various implementations of the disclosure discussed herein. In similar fashion, while certain implementations may be discussed below as device, system, or method implementations it should be understood that such implementations can be implemented in various devices, systems, and methods.

### BRIEF DESCRIPTION OF THE DRAWINGS

FIG. 1 is a front perspective illustration of an interposer connected to a device under test and to a rigid PCB in accordance with one or more aspects of the disclosure.

FIG. 2 is a side perspective illustration of the interposer of FIG. 1.

FIG. 3 is a top view of an interposer configured to connect a device under test (DUT) to a PCB and thereby expose test signals of the DUT in accordance with one or more aspects of the disclosure.

FIG. 4 is a schematic diagram illustrating a first signal layer of an interposer including conductive traces in accordance with some aspects of the disclosure.

FIG. 5 is a schematic diagram of multiple layers of an interposer in accordance with some aspects of the disclosure.

FIG. 6 is a schematic diagram illustrating a first array of conductive rings formed in a first pattern on a first section of the substrate and a second array of conductive rings formed in a second pattern on a second section of the substrate in accordance with some aspects of the disclosure.

FIG. 7A is a perspective exploded view of a portion of an interposer and a BGA device under test (DUT) before the DUT is attached to the interposer in accordance with some aspects of the disclosure.

FIG. 7B is a perspective view of the portion of the interposer and the DUT of FIG. 7A after attachment in accordance with some aspects of the disclosure.

FIG. 8 is a perspective view of an array of conductive rings on a substrate and an enlarged perspective illustration of one of those conductive rings, in accordance with some aspects of the disclosure.

FIG. 9 is a flowchart illustrating a method for connecting a device under test to a PCB with an interposer in accordance with some aspects of the disclosure.

FIG. 10 is a flowchart illustrating another method for connecting a device under test to a PCB with an interposer in accordance with some aspects of the disclosure.

### DETAILED DESCRIPTION

In the following detailed description, reference is made to the accompanying drawings, which form a part thereof. In addition to the illustrative aspects, embodiments, and features described above, further aspects, embodiments, and features will become apparent by reference to the drawings and the following detailed description. The description of elements in each figure may refer to elements of proceeding figures. Like numbers may refer to like elements in the figures, including alternate embodiments of like elements.

The examples herein relate to interposers used to connect ball grid array (BGA) devices to printed circuit boards (PCBs). In the examples described herein, the device under test may be a surface-mount device such as an SSD (e.g., SSD using NAND flash memory) with a BGA package. The SSD often includes NAND memory which is a type of non-volatile storage technology that does not require power to retain data. It exploits negative-AND, i.e., NAND, logic. It is understood that at least some aspects described herein may be used for connecting an SSD in a BGA package, being the device under test, to a PCB with an interposer.

As described above, in prior approaches a BGA component/device is attached to or detached from a PCB using dedicated equipment (e.g., a rework solder machine or heat blower gun which is considered uncontrolled and may easily cause damage to the BGA device) in a specialized lab. The BGA component itself is attached using its array of ball connectors (e.g., solder balls formed on ball pads), often formed of tin. During field investigations (e.g., at a customer site) a failed BGA component that is under investigation (e.g., DUT) may need to be detached from and resoldered to a PCB. However, this is not easy, or even possible in some cases, for a number of reasons. First, a rework solder machine is often not available at a customer site or access thereto is very limited. This may create delays or even prevent necessary investigation steps for a technician (e.g., a field application engineer or manufacturer engineer) Second, for proper failure analysis, the BGA component should be kept in its original state without any environmental effect (e.g., heat exposure that may result in data loss). As such, the DUT can be removed by mechanical means, without any heat exposure. In one aspect, this can be done by a third party, out of the customer's premises. However, soldering the DUT back to a new/replacement PCB generally requires re-balling of the DUT that exposes it to heat stress. This process generally cannot be done by a third party, since most customers will not allow the DUT manufacturer engineers and/or the third party to take a customer PCB outside of its premises, for security reasons. Using a rework solder machine will expose the unit to heat, which may change its internal status (e.g., for example NAND cells bit error rate (BER) level may change).

To address the above problems, the interposers and corresponding processes described herein allow for a quick removal and re-connection (without re-balling) of the BGA component (DUT) to the PCB using a simple soldering iron, and without a dedicated rework/soldering machine. With this method the DUT will not be exposed to heat, or only exposed to the very limited and localized heating of a simple soldering iron, and will thus stay in its original state, which in many cases may be important for a proper investigation. For example, heat, such as the heat applied by a rework solder machine, may cause irreversible damage to the DUT or to adjacent host circuitry.

Embodiments of interposers (or interposer assemblies) and methods of attachment described herein involve a unique interposer structure configured to enable the above noted removal and re-connection (without re-balling) of the BGA component (DUT) to a PCB using a simple soldering iron. The use of the simple soldering iron, as compared to the rework solder machine, features exposing only a small portion of one side of the DUT to heat, at a lower temperature than that of the rework solder station, for a relatively short time (notably shorter than that of the rework solder station). One such interposer assembly includes a ball grid array including an array of ball pads; a flexible substrate; a first array of conductive rings formed in a first pattern on the flexible substrate, where the first array of conductive rings is attached to the array of ball pads such that at least one conductive ring of the first array of conductive rings is attached to one ball pad of the array of ball pads; a second array of conductive rings formed in a second pattern on the flexible substrate; and a plurality of conductive traces connecting conductive rings of the first array to conductive rings of the second array. The BGA device may have damaged ball connectors (e.g., solder balls) as a result of a mechanical removal process to separate the BGA device from the original PCB to which it was mounted. In one aspect, the damaged solder balls can be removed with the soldering iron before it is attached to the flexible substrate (e.g., interposer).

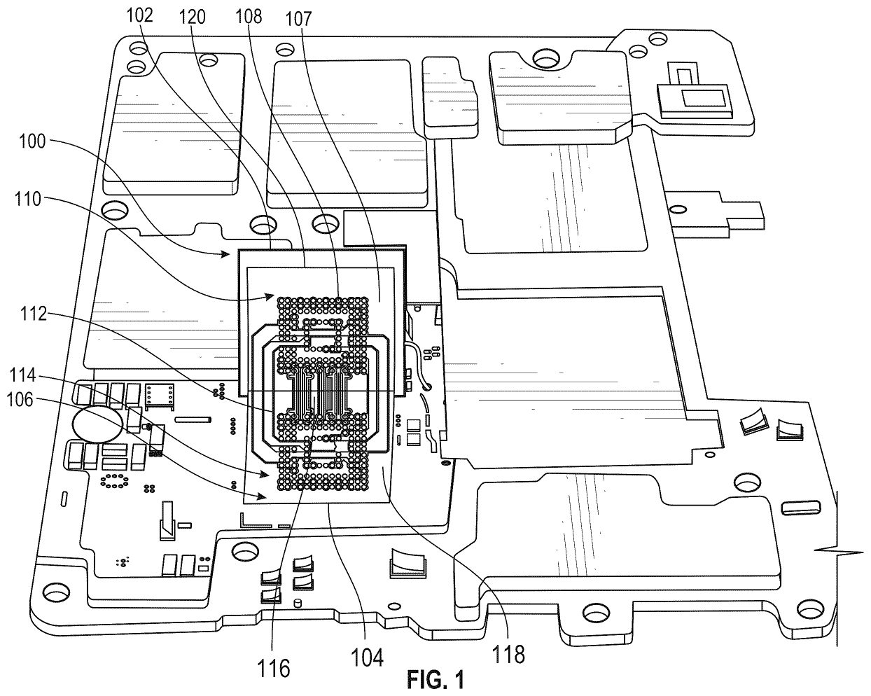

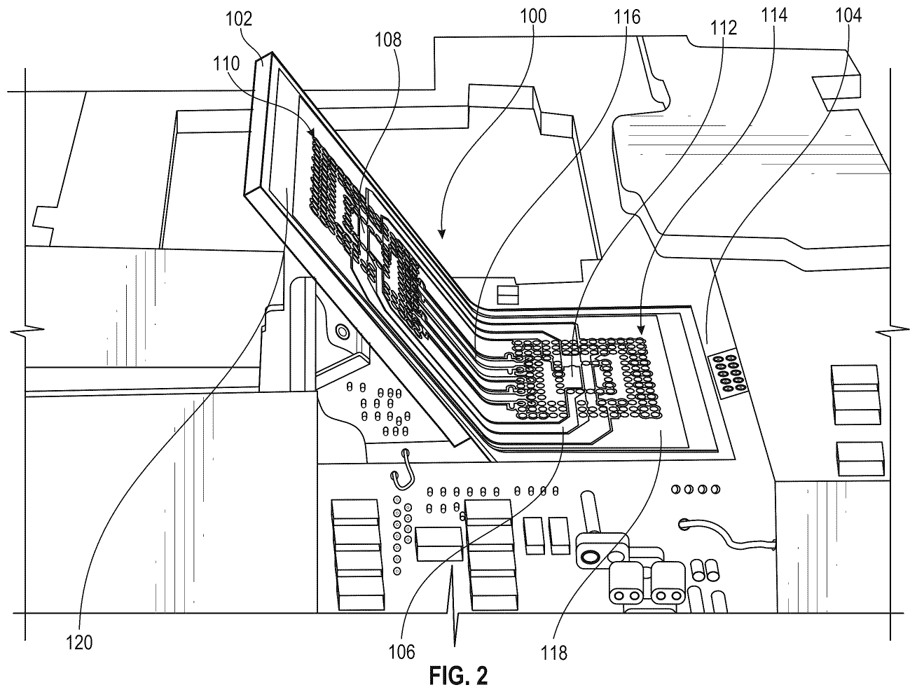

FIG. 1 is a front perspective illustration of an interposer 100 connected to a device under test 102 and a PCB 104 in accordance with one or more aspects of the disclosure. FIG. 2 is a side perspective illustration of the interposer 100 of FIG. 1. Referring now to both FIGS. I and 2, the interposer 100 includes a flexible circuit board 106. The flexible circuit board 106 includes a flexible substrate 107 and a first array of conductive rings 108 (not visible but disposed beneath the corresponding solder blobs) formed in a first pattern 110 on the flexible substrate 107. The first array of conductive rings 108 has been soldered to ball pads (not visible but disposed on the surface of the device under test) of the device under test 102 (e.g., BGA device), which includes a ball grid array connection interface in the form of an array of the ball pads. In one aspect, the interposer 100 and BGA 102 (e.g., coupled together) can be referred to as an interposer assembly.

The flexible printed circuit board 106 further includes a second array of conductive rings 112 (not visible but disposed beneath the corresponding solder blobs) formed in a second pattern 114 on the flexible substrate 107. The second array of conductive rings 112 has been soldered to connectors (e.g., BGA pads) of a PCB 104 (a rigid PCB).

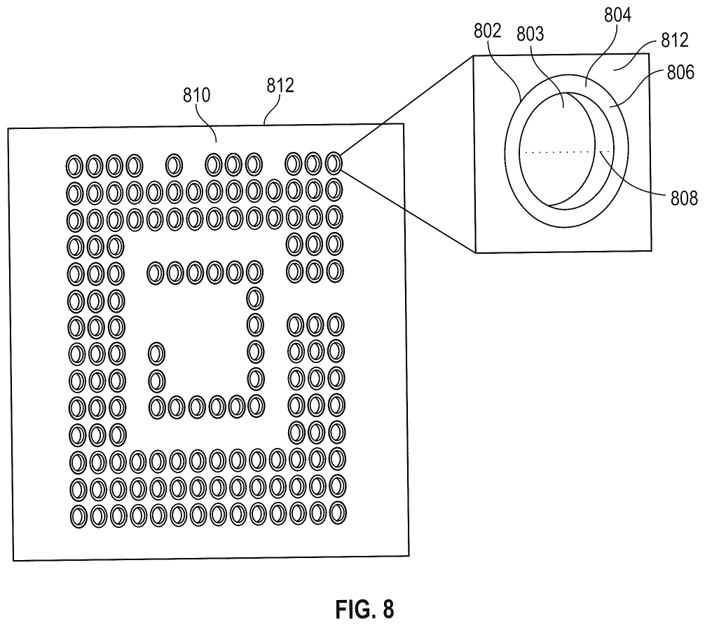

While not visible in FIGS. 1-2 (but see for example FIG. 8), each conductive ring in the first array of conductive rings 108 and each conductive ring in the second array of conductive rings 112 is formed within a hole, which is shaped as a cylindrical hole, through the flexible printed circuit board 106, using a conductive material coated on the walls formed by the cylindrical hole, where the conductive material has its own cylindrical hole and forms the conductive ring at an outer surface of the flexible printed circuit board 106.

The first array of conductive rings 108 is coupled to ball pads of the device under test 102, which is a ball grid array (BGA) device, such as an SSD with a BGA package. In a number of embodiments, the first array of conductive rings 108 can be coupled directly to the ball pads of the BGA device after the solder balls, and in some cases damaged solder balls, of the BGA have been removed, such as by de-soldering them from the BGA device with a simple soldering iron. In certain embodiments, the first array of conductive rings 108 can also be coupled to damaged solder balls left on the ball pads (or at least some small portion thereof) after the DUT 102 is removed from the PCB 104. In one aspect, the first array of conductive rings 108 is attached to the ball pads of the device under test 102 by applying heat and solder paste to the conductive rings (e.g., while the rings are aligned and in contact with the ball pads). As the solder paste melts (e.g., at one end of a conductive ring at a first section 118 of the interposer), it fills the conductive ring 108 and flows through to the ball pad to thereby electrically and physically connects to the corresponding ball pad to the conductive ring (e.g., at the other end of the conductive ring on an opposite surface of the interposer). In one aspect, one or more of the connections may be made using a simple soldering iron.

The second array of conductive rings 112 formed in a second pattern 114 on the flexible printed circuit board 106 has been attached to connectors (e.g., BGA pads) of the rigid PCB 104. In one aspect, the second array of conductive rings 112 is attached to connectors of the rigid PCB 104 by applying heat and solder paste to the conductive rings. As the solder paste melts, it fills and flows through the conductive rings 112 and thereby electrically and physically connects the rigid PCB connectors (BGA pads that generally have a planar shape) to the conductive rings. In one aspect, one or more of the second array connections may be made using a simple soldering iron. One or more conductive traces 116 on the flexible printed circuit board 106 connect the first array of conductive rings 112 and second array of conductive rings 112.

In certain embodiments, the first pattern 110 on the flexible printed circuit board 106 and the second pattern 114 on the flexible printed circuit board 106 are identical or substantially the same. For example, the first pattern 110 on the flexible printed circuit board 106 is selected to match a ball pad pattern on the device under test 102. In certain embodiments, the first pattern 110 on the flexible printed circuit board 106 and the second pattern 114 on the flexible printed circuit board 106 are different.

In certain embodiments, the first array of conductive rings 108 formed in the first pattern 110 on the flexible printed circuit board 106 is positioned at a first section 118 of the flexible printed circuit board 106, and the second array of conductive rings 112 formed in the second pattern 114 on the flexible printed circuit board 106 is positioned at a second section 120 of the flexible printed circuit board 106. The first section 118 is positioned at one end of the flexible PCB 106 and the second section 120 is positioned at an opposite end to the first section 118. In certain embodiments, the first section 118 can correspond to roughly one half of the flexible printed circuit board 106 and the second section 120 can correspond to the other half of the flexible printed circuit board 106.

FIG. 2 is a side perspective illustration of the interposer of FIG. 1. As can be seen in FIGS. 1 and 2, the interposer is configured to connect the DUT 102 (with the BGA package) to the rigid PCB 104 using a set of conductive rings that function like pads but do not include traditional planar conductive pads (e.g., pads formed of an exposed conductive metal with a planar shape that extends along an outer surface of a PCB to enable connection to a lead/ball of a BGA device). In the aspects presented in FIGS. 1 and 2, the DUT 102 and the rigid PCB 104 are coupled to the same side of the interposer 100. However, the interposer 100 is configured such that the DUT 102 and the rigid PCB 104 may be coupled to opposite sides of the interposer 100 if the arrangement of components so requires.

By using this interposer structure and a traditional simple soldering iron, a technician can solder the DUT 102 to the interposer 100 and the rigid PCB 104 to the interposer 100 without using a rework solder station that might damage the DUT 102. This can enable the technician, or someone else, easy access to signals of the DUT (BGA device). Additional details regarding these attachment procedures will be discussed below.

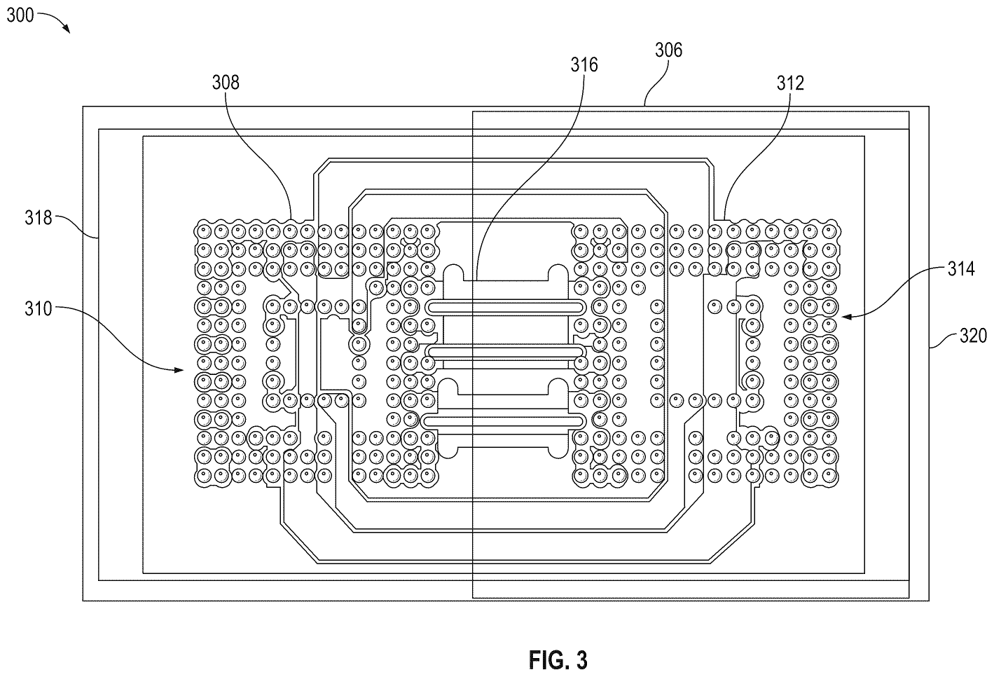

FIG. 3 is a top view of an interposer configured to connect a device under test to a PCB in accordance with one or more aspects of the disclosure. Certain aspects of the interposer 300 may be substantially similar to aspects of interposer 100. The interposer 300 includes a substrate 306, with a first array of conductive rings 308 formed in a first pattern 310 on a first section 318 of the substrate 306. The first array of conductive rings 308 is configured to couple to ball pads of a ball grid array device.

The interposer 300 further includes a second array of conductive rings 312 formed in a second pattern 314 on a second section 320 of the substrate 306. The second array of conductive rings 312 is configured to couple to connectors of a printed circuit board. One or more conductive traces 316 connect the first array of conductive rings 308 and the second array of conductive rings 312.

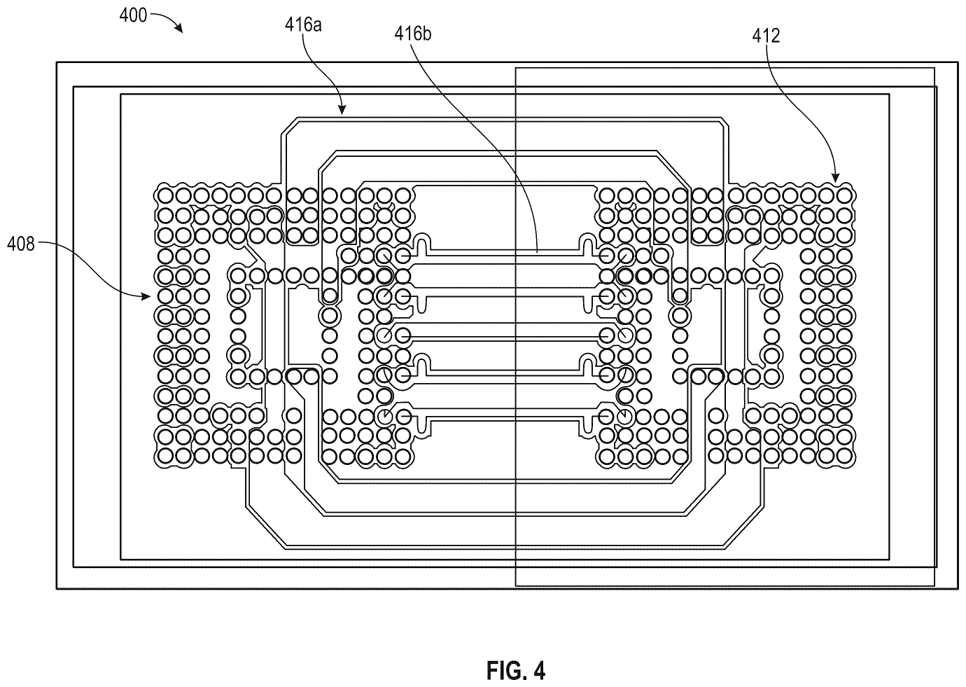

FIG. 4 is a schematic diagram illustrating a first signal layer of an interposer including conductive traces in accordance with some aspects of the disclosure. Certain aspects of the interposer 400 may be similar to aspects of interposers 100 or 300. The first signal layer includes a first array of conductive rings 408 and a second array of conductive rings 412 formed within the interposer 400. Various conductive rings of the first array of conductive rings 408 are coupled by one or more conductive traces (416a, 416b) to various conductive rings of the second array of conductive rings 412. In one aspect, each of the conductive rings of the first array 408 is coupled to a corresponding (e.g., corresponding in position within the arrays) conductive ring of the second array 412 using one or more conductive traces. In one aspect. only selected conductive rings of the first array 408 are coupled to corresponding (e.g., corresponding in position within the arrays) conductive rings of the second array 412 (e.g., in use cases where not every pin of the corresponding BGA device is used). Conductive traces 416a can couple one conductive ring to another conductive ring with a standard trace size. Conductive traces 416b can couple one conductive ring to another conductive ring with an expanded trace size (e.g., larger than the standard sized traces and possibly used for various power and/or ground signals).

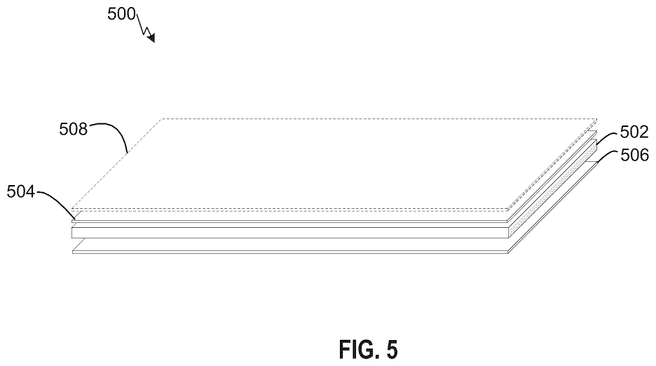

FIG. 5 is a schematic diagram of multiple layers of an interposer in accordance with some aspects of the disclosure. The interposer 500 is implemented with a flexible substrate 500 which may correspond with for example flexible substrate 106 of FIGS. 1-2. The flexible substrate 500 can have multiple layers including a two-sided base layer 502 and a first insulation layer (e.g., top coating layer made of an insulating material) 504, a second insulation layer (e.g., bottom coating layer made of an insulating material) 506, and an optional silkscreen layer 508 (e.g., for printed symbols). Base layer 502 includes a top side and a bottom side, where each side includes signal and ground traces formed in part by the respective first and second insulation layers. In one aspect, the flexible substrate 500 can include another optional silkscreen layer (not shown) disposed on the second insulation layer 506. The optional silkscreen layers can be provided to add symbols or characters to provide descriptions relating to the interposer, such as interposer 100 or components thereon.

The base layer 502 can be made of a polyimide, or other such flexible material that is also not electrically conductive. The base layer 502 can include conductive traces (not shown but see 416a, 416b in FIG. 4) which can be implemented using copper traces, or other suitable conductive materials, where the conductive traces are formed on the polyimide.

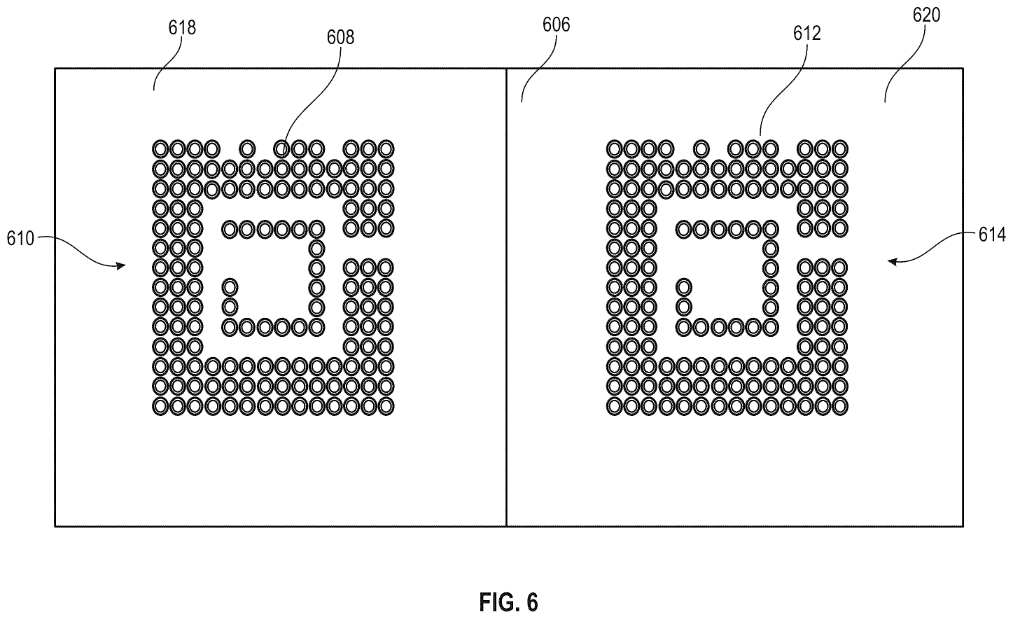

FIG. 6 is a schematic diagram illustrating a first array of conductive rings 608 formed in a first pattern 610 on a first section 618 of the substrate and a second array of conductive rings 612 formed in a second pattern 614 on a second section 620 of the substrate in accordance with some aspects of the disclosure. In one aspect, the first pattern 610 can be selected to match a ball pad pattern of the array of ball pads of the BGA device. While the first pattern 610 on the substrate 606 need not be identical to the ball pad pattern of the BGA device, in certain embodiments, the first pattern 610 on the substrate 606 can be selected to match, or substantially match, the ball pad pattern of the array of ball pads of the BGA device.

Likewise, the second pattern 614 can be selected to match a preselected connection pattern, such as a ball pattern of the connectors of a rigid PCB (e.g., pattern of (planar) ball pads configured to be attached to ball connectors of a BGA device). While the second pattern 614 need not be identical to the connection pattern (e.g., pad array) of the rigid PCB, in certain embodiments, the second pattern 614 can be selected to match, or substantially match, the connection pattern of the rigid PCB. In certain embodiments, the first pattern 610 and the second pattern 614 may be identical or may be substantially the same.

The first array of conductive rings 608 formed in the first pattern 610 on the substrate 606 is positioned in the first section 618 of the substrate 606 and the second array of conductive rings 612 formed in the second pattern 614 on the substrate 606 is positioned at a second section 620 of the substrate 606. The first section 618 and the second section 620 can be positioned at opposite ends of the substrate 606.

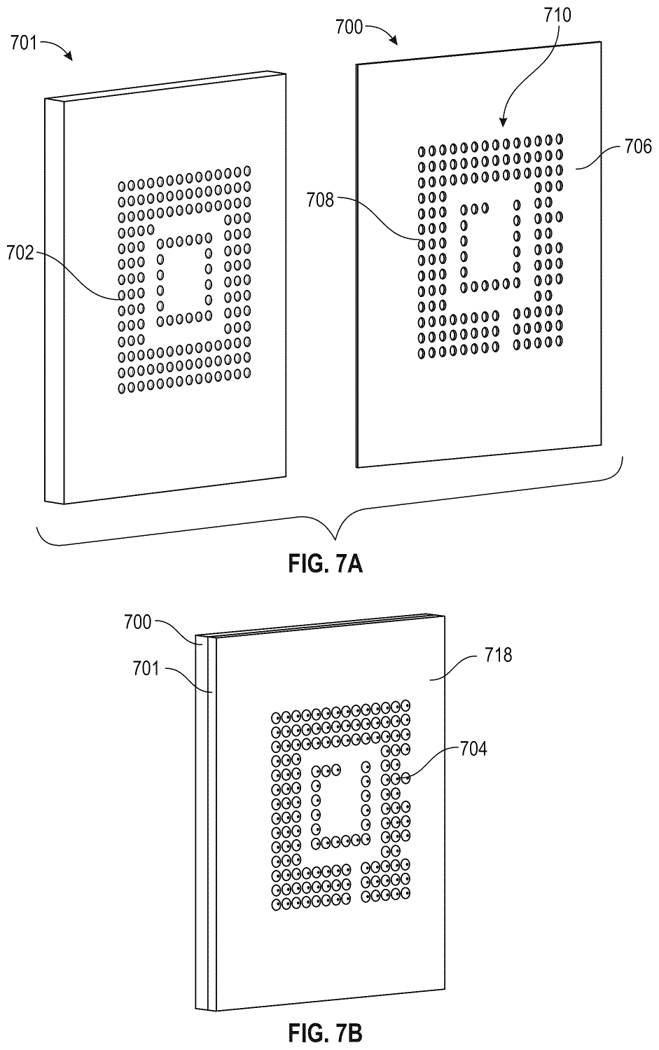

FIG. 7A is a perspective exploded view of a portion of an interposer 700 and a BGA device under test (DUT) 701 before the DUT 701 is attached to the interposer in accordance with some aspects of the disclosure. The device under test 701 has an array of ball pads arranged in a ball pad pattern 702. The interposer 700 includes a substrate 706 and a first array of conductive rings 708 formed in the first pattern 710 in the substrate 706. Before the device under test 701 is connected to the interposer 700, the conductive rings 708 are not filled and there is no mechanical or electrical connection between the device under test 701 and interposer 700

In one example, the device under test 701, is a surface-mount device such as an SSD or NAND with a BGA package. The device under test 701 has the pattern of ball pads 702 which is also the pattern of the BGA for that device. Each of the ball pads in the array 702 has a shape consistent with a BGA package and is configured for attachment to a PCB via solder balls which are normally formed on the respective ball pads, originally by the BGA manufacturer and later by a technician attempting reattachment (using a complicated re-balling process) should the BGA be removed. In some examples, the original BGA solder balls may be damaged. The damage to the solder balls may have resulted from the removal of the BGA device 701 from a printed circuit board (e.g., a PCB of a device identified with one or more functional problems). Removal of the BGA device 701 from a printed circuit board, can be achieved by mechanical means, including grinding and/or polishing, which may damage the solder balls (e.g., ball connectors) of the pattern of ball connectors 702. The damaged solder balls can be removed from the ball pads arranged in the ball pad pattern 702. The ball pads can be cleaned after the removal of the damaged solder balls, to remove residual material left on the ball pads. In this way, the array of ball pads does not include solder balls. This is different from traditional attachment procedures for a BGA device where the solder balls are pre-positioned on the ball pads to facilitate attachment of all of the ball pads at once as the entire BGA device (or at least the surface with the ball pads and solder balls) is heated along with the substrate (e.g., PCB) to which the BGA will be attached. In contrast to the traditional BGA attachment procedures, the ball pads used in the inventive procedures described herein do not have attached solder balls, or possibly have some minimal remnants of prior solder balls, and the ball pads are attached to the interposer in a one by one fashion with a simple solder iron. along with newly applied solder. The ball pads 702 can have a planar circular, or substantially planar circular shape, or other suitable shape as in known in the art. The ball pads 702 are formed of an electrically conductive material such as a conductive metal (e.g., tin, copper, or the like) along an outer surface of the BGA device.

The first pattern 710 associated with first array of conductive rings 708 formed in the substrate 706 can be selected to match or very nearly match, the pattern of ball pads 702 of the device under test 701.

It should be appreciated that the interposer does not include a planar conductive pad that is configured to couple to a connector of a ball grid array device, for example, as might be used by a conventional PCB configured to attach to the BGA device. As used herein, a planar conductive pad refers to a pad formed of an exposed conductive metal with a planar shape that extends along an outer surface of a PCB (rigid or flexible) such as the interposer.

FIG. 7B is a perspective view of the interposer 700 and the DUT 701 of FIG. 7A after attachment, which can collectively be referred to as an interposer assembly, in accordance with some aspects of the disclosure. A portion of the substrate 706 (e.g., first section 718) of the interposer 700 is directly attached to the device under test 701. It should be understood that this illustration is exemplary, and another illustration could illustrate another portion of the substrate 706 (e.g., second section 120) of the interposer 700, directly attached to a rigid PCB, such as is illustrated in FIGS. 1-2.

The interposer 700 can be connected directly to the device under test 701 at the first section 118 and, in a separate attachment step, to the rigid PCB at the second section 120 (the latter is not shown in FIG. 7B but see FIGS. 1-2). The direct connection between the device under test 701 and the interposer 700 can be realized by aligning the first array of conductive rings 708 with the ball pads (e.g., 702) of the device under test 701. Solder paste 704 and heat can be applied to each conductive ring in the first array of conductive rings 708 (e.g., one by one) to electrically bond the conductive rings to respective ball pads 702 of the BGA device 701. The ball pads 702 of the BGA device 701 are thus soldered to the first array of conductive rings 708 using a simple soldering iron. In one aspect, the ball pads 702 are soldered to the conductive rings 708 one by one.

The direct connection between the rigid PCB and the interposer 700 can similarly be realized by aligning the second array of conductive rings (not shown but see conductive rings 112 in FIGS. 1-2 on the substrate 106 which may be equated to substrate 706 of FIG. 7B for this example) with connectors of the rigid PCB. Solder paste and heat can be applied to each conductive ring in the second array of conductive rings 112 to electrically bond the conductive rings to respective connectors/pads of the rigid PCB. The connectors/pads of the rigid PCB are thus soldered to the second array of conductive rings 112 to connect the substrate 706 to the rigid PCB using a simple soldering iron. In one aspect, the BGA pads of the rigid PCB are soldered to the conductive rings 112 one by one. This is in contrast to the traditional method of BGA attachment which, as noted above, heats the entire BGA (or a surface of the BGA having the solder balls) and the PCB (or at least a localized portion of the PCB) to facilitate attachment of the BGA pads to the PCB using the preinstalled solder balls.

FIG. 8 is a perspective view of an array of conductive rings on an interposer substrate and an enlarged perspective illustration of one of those conductive rings, in accordance with some aspects of the disclosure. Each conductive ring in the first array of conductive rings 810 and each conductive ring in the second array of conductive rings (e.g., second array of conductive rings 112) may be formed from a cylindrical hole 802 through the flexible substrate 812 and a conductive material 804 coated on walls 806 formed by the cylindrical hole 802 through the flexible substrate 812. Each ring also includes its own cylindrical hole 803 which is configured to receive and facilitate spread of solder paste during a soldering procedure. The diameter 808 of each cylindrical hole 803 can be smaller than a diameter (or other corresponding dimension) of a ball pad of the ball grid array. In certain embodiments, the diameter of the conductive ring can be about 10 to 15 millimeters (e.g., 12.7 mils plus or minus 2 mils), in order to fit on the ball pads of the ball grid array and/or on the connectors of a printed circuit board. Each conductive ring 810 of the first array of conductive rings can be substantially aligned with a center of the corresponding ball pad of the array of ball pads of the ball grid array device and attached to a corresponding ball pad of the array of ball pads of the ball grid array device.

The conductive material 804 forms the conductive ring with a hollowed cylindrical shape that extends through the flexible substrate 812, and possibly just slightly beyond each outer surface of the flexible substrate. In one aspect, the conductive material 804 can be copper. In one aspect, other suitable conductive materials can be used. In one aspect, the conductive material 804 is copper and is also plated with tin. In one aspect, the conductive rings are formed by a fabrication process that involves drilling through the flexible PCB 812 using a mechanical drill or a laser and then plated with copper and/or tin.

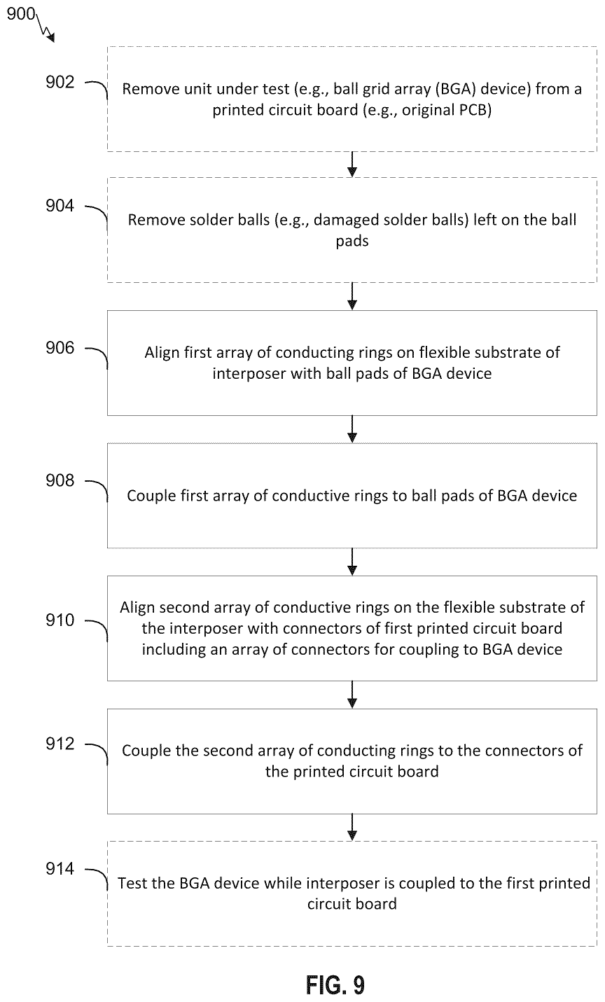

FIG. 9 is a flowchart illustrating a method for connecting a device under test to a PCB with an interposer in accordance with some aspects of the disclosure. In one aspect, the method/process 900 may be performed by a technician using an interposer as illustrated by any of FIGS. 1-8, to connect a device under test, such as an SSD with a BGA package, to a printed circuit board.

A BGA device is most commonly attached to a rigid PCB. The BGA device includes an array of solder balls (e.g., ball connectors), often formed of tin, on BGA pads that may be used to attach to pads on the rigid PCB. During field investigations of a device/design with a BGA component (e.g., at a customer site) many times a suspected or failed BGA component that is under investigation (e.g., DUT) needs to be soldered or resoldered to a different PCB so that diagnostics or other tests can be performed on the DUT using a PCB that is known to be operating correctly (e.g., a known good PCB).

At optional block 902, a device under test (e.g., BGA component/device) can be removed from the original rigid PCB to which it is mounted. In order to remove the BGA device from the original rigid PCB, mechanical means, such as grinding and polishing are often used. Removal of a BGA device from a rigid PCB can be a difficult process, and often results in either damage to the PCB or the BGA device. To properly troubleshoot the BGA device (DUT here), it is important not to change the characteristics of the BGA device during removal. which means it is preferable to apply little or no heat to the BGA device during removal (i.e., to remove the DUT without the use of a standard rework solder machine). Removing the BGA device by mechanical means to avoid changing the characteristics (e g., such as information stored in a memory of the BGA device)) may however cause damage to one or more solder balls (e.g., ball connectors) in the array of solder balls (e.g., ball connectors) of the BGA device (e.g., due to the grinding procedure described above).

Removing the BGA device from the original rigid PCB may include removing the BGA device from the rigid PCB without using a machine that generates evenly dispersed heat, such as the rework solder machine, and without using a device that provides uncontrolled dispersed heat such as a heat blower gun (e.g., which may easily cause damage to the BGA device). In a number of cases, removal of the BGA device from the rigid PCB may involve partial or full destruction of the rigid PCB. In such case, subsequent actions associated with this process (e.g., such as actions described in blocks 908, 910, and 912) can involve use of a replacement rigid PCB (e.g., one that is effectively the same as the original rigid PCB except that no BGA component (e.g., DUT) has been attached thereto).

In prior approaches, soldering the DUT back to the new PCB generally required re-balling of the DUT using a standard rework solder machine. This technique exposes the DUT to undesirable heat stress. This process generally cannot be performed by a third party (e.g., a party other than the customer or the troubleshooting engineer), since the DUT may be required to stay at a certain home facility for security reasons, or simply for practicality. As noted above, using a rework solder machine will expose the DUT to heat, which may change its internal status (e.g., memory, register status, or other stored configuration settings).

Once the DUT has been removed from the original rigid PCB (e.g., by the mechanical means to avoid damage to BGA device integrity), at optional block 904 one or more of the solder balls on the ball pads are removed, as well as any remaining solder ball material on the ball pads. For example, residual material from the solder balls, left on the ball pads after mechanical disconnection of the DUT from the original PCB, can be removed without the application of uniform heating (e.g., with a standard rework solder machine). Instead, any residual material from the solder balls can be removed with a simple solder iron.

Once the solder balls have been removed, at block 906 a first array of conductive rings on the flexible substrate is aligned with ball pads on the ball grid array device. More specifically, conductive rings corresponding in position with ball pads on the BGA device are aligned.

At block 908, the first array of conductive rings is coupled to ball pads of the ball grid array device. Coupling the first array of conductive rings to the ball pads of the ball grid array device may include coupling the first array of conductive rings to the ball pads of the ball grid array device without using a machine that generates evenly dispersed heat, such as a rework solder machine. In one aspect the coupling may be accomplished with a simple soldering iron, which does not generate evenly dispersed heat. As compared to the rework solder machine, the simple soldering iron generates localized heat rather than evenly dispersed heat and at a lower temperature than that of the rework solder machine.

Each of the first array of conductive rings is formed from a conductive material coated on walls of a cylindrical hole through (e.g., drilled through) the flexible substrate, where the conductive material forms a shape similar to a hollowed cylinder with a cylindrical hole of its own. At the surface of the flexible substrate, the conductive material appears as a ring (e.g., the conductive ring). In operation, heat (e.g., from a simple soldering iron) and solder (e.g., solder paste) can be applied to each conductive ring on one side of the flexible substrate. The heat from the simple soldering iron and/or gravity causes the solder to flow through the conductive ring and bond (e.g., electrically and physically bond) to respective ball connectors (e.g., ball pads, or damaged ball connectors) of the BGA device (e.g., which are positioned against a surface of the flexible substrate opposite to the surface where the heat and solder were applied). This process may be repeated for each conductive ring (e.g., in a sequential manner) until the array of conductive rings is bonded to the BGA device ball pads. In one aspect, each conductive ring is bonded to a corresponding BGA device ball pad. In one aspect, not all conductive rings are bonded to a corresponding BGA device ball pad.

Once the first array of conductive rings is coupled to the ball pads of the BGA device, at block 910, the second array of conductive rings on the substrate is aligned with connectors (e.g., PCB pads configured for attached to a BGA device) of a rigid printed circuit board. At block 912, the second array of conductive rings is operably connected to the connectors of the rigid PCB. Coupling the second array of conductive rings to the connectors of the rigid PCB may include coupling the second array of conductive rings to the connectors of the rigid PCB without using a machine that generates evenly dispersed heat, such as a rework solder machine. In one aspect the coupling may be accomplished with a simple soldering iron, which does not generate evenly dispersed heat.

The coupling is accomplished by taking advantage of the cylindrical hole through the conductive material of the second array of conductive rings. Similar to the first array of conductive rings, each of the second array of conductive rings is formed from the conductive material coated on walls of a cylindrical hole through (e.g., drilled through) the flexible substrate, where the conductive material forms a shape similar to a hollowed cylinder with a cylindrical hole of its own. At the surface of the flexible substrate, the conductive material appears as a ring (e.g., the conductive ring). In operation, heat (e.g., from a simple soldering iron) and solder (e.g., solder paste) can be applied to each conductive ring on one side of the flexible substrate. The heat from the simple soldering iron and/or gravity causes the solder to flow through the conductive ring and bond (e.g., electrically and physically bond) to respective ball connectors (e.g., BGA pads) of the rigid PCB (e.g., which are positioned against a surface of the flexible substrate opposite to the surface where the heat and solder were applied). This process may be repeated for each conductive ring (e.g., in a sequential manner) until the array of conductive rings is bonded to the BGA pads. In one aspect, each conductive ring is bonded to a corresponding BGA pad. In one aspect, not all conductive rings are bonded to a corresponding BGA pad.

The interposers and corresponding processes described herein allow for a relatively quick connection/re-connection (without re-balling) of the BGA component (DUT) to a flexible PCB (interposer) and a rigid PCB using a simple soldering iron, and without a dedicated rework/soldering machine. With this method the DUT will not be exposed to heat (e.g., substantial and damaging heat), or only exposed to the limited and local heating of a simple soldering iron, and will thus stay in its original state which in many cases is critical for the investigation. Heat in many cases, such as the heat applied by a rework solder machine, causes irreversible damage to the DUT or adjacent host circuitry. The use of the simple soldering iron, as compared to the rework solder machine, only exposes a small portion of one side of the DUT to beat, at a lower temperature than that of the rework solder station, for a relatively short time, as compared to similar processes at a rework solder station.

At optional block 914 the ball grid array device is tested while the interposer is coupled to the printed circuit board. More specifically, the interposer exposes the BGA connector signals for analysis and/or troubleshooting by a field test engineer.

In one aspect, the actions of blocks 910 and 912 can be performed prior to the actions of blocks 906 and 908 such that the interposer is first attached to the rigid PCB (e.g., replacement rigid PCB as differentiated from the original rigid PCB) and then attached to the BGA device.

The method 900 may be realized, at least in part, because the interposer has a flexible substrate. For example, the location of the BGA device on the original rigid PCB may not be conveniently accessible for attachment thereto, particularly by another rigid PCB or other such means. In addition, the original rigid PCB may have a crowded or tightly integrated design. The flexible substrate allows the first section of the interposer connected to the device under test, to be in a different plane from that of the PCB, and the second section connected to the PCB.

The method 900 can include selecting a first pattern of the first array of conductive rings on the substrate to match a pattern of the ball pads of the ball grid array device, and selecting a second pattern of the second array of conductive rings on the substrate to match a pattern of the connectors (e.g., PCB pads) of the printed circuit board. The first pattern of conductive rings in the first array of conductive rings on the substrate and a second pattern of conductive rings in the second array of conductive rings on the substrate can be identical, or substantially the same.

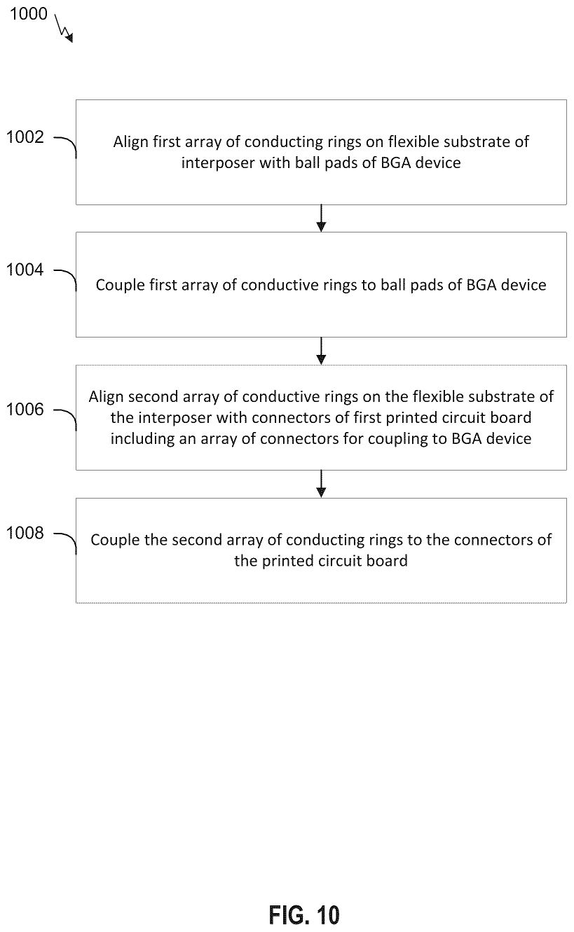

FIG. 10 is a flowchart illustrating another method for connecting a device under test to a PCB with an interposer in accordance with some aspects of the disclosure. In one aspect. the method/process 1000 may be performed by a technician using an interposer as illustrated by any of FIGS. 1-8, to connect a device under test, such as an SSD with a BGA package, to a printed circuit board. At block 1002, a technician aligns a first array of conductive rings on a flexible substrate of the interposer to ball pads of a ball grid array (BGA) device). In one aspect, this action can be performed in accordance with the action of block 906 of FIG. 9. At block 1004, a technician couples the first array of conductive rings to the ball pads of the BGA device In one aspect, this action can be performed in accordance with the action of block 908 of FIG. 9. At block 1006, a technician aligns a second array of conductive rings on the flexible substrate of the interposer with connectors of a first printed circuit board including an array of connectors for couple to the BGA device. In one aspect, this action can be performed in accordance with the action of block 910 of FIG. 9. At block 1008, a technician couples the second array of conducting rings to the connectors of the printed circuit board. In one aspect, this action can be performed in accordance with the action of block 912 of FIG. 9.

The disclosed apparatus also provides an interposer for connecting a device under test to a printed circuit board. The apparatus and associated methods are designed to be relatively simple, and can be completed by technicians with little or no training. Likewise, the disclosed embodiments minimize the application of heat to the device under test, preserving the integrity of the associated components. Previous methods for coupling a device to a PCB require heat treatment for reballing with a rework tool, which jeopardized the integrity of the components of the device under test. The interposers disclosed herein can save technician time and resources by enabling simple connections between the device under test and PCB, for faster turnaround times, that do not require an engineer to perform solder rework on the device under test.

Although the embodiments described herein primarily involve SSDs (e.g., such as NAND devices) as exemplary devices, a variety of units under test may be connected to PCBs using the apparatuses and methods provided herein.

The examples set forth herein are provided to illustrate certain concepts of the disclosure. The apparatuses, devices, or components illustrated above may be configured to perform one or more of the methods, features, or steps described herein. Those of ordinary skill in the art will comprehend that these are merely illustrative in nature, and other examples may fall within the scope of the disclosure and the appended claims. Based on the teachings herein those skilled in the art should appreciate that an aspect disclosed herein may be implemented independently of any other aspects and that two or more of these aspects may be combined in various ways. For example, an apparatus may be implemented, or a method may be practiced using any number of the aspects set forth herein. In addition, such an apparatus may be implemented or such a method may be practiced using other structure, functionality, or structure and functionality in addition to or other than one or more of the aspects set forth herein.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks.

The subject matter described herein may be implemented in hardware, software, firmware, or any combination thereof. As such, the terms “function,” “module,” and the like as used herein may refer to hardware, which may also include software and/or firmware components, for implementing the feature being described. In one example implementation. the subject matter described herein may be implemented using a computer readable medium having stored thereon computer executable instructions that when executed by a computer (e.g., a processor) control the computer to perform the functionality described herein. Examples of computer readable media suitable for implementing the subject matter described herein include non-transitory computer-readable media, such as disk memory devices, chip memory devices, programmable logic devices, and application specific integrated circuits. In addition, a computer readable medium that implements the subject matter described herein may be located on a single device or computing platform or may be distributed across multiple devices or computing platforms.

It should also be noted that, in some alternative implementations, the functions noted in the blocks may occur out of the order noted in the figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated figures. Although various arrow types and line types may be employed in the flowchart and/or block diagrams, they are understood not to limit the scope of the corresponding embodiments. For instance, an arrow may indicate a waiting or monitoring period of unspecified duration between enumerated steps of the depicted embodiment.

The various features and processes described above may be used independently of one another, or may be combined in various ways. All possible combinations and sub-combinations are intended to fall within the scope of this disclosure. In addition, certain method, event, state or process blocks may be omitted in some implementations. The methods and processes described herein are also not limited to any particular sequence, and the blocks or states relating thereto can be performed in other sequences that are appropriate. For example, described tasks or events may be performed in an order other than that specifically disclosed. or multiple may be combined in a single block or state. The example tasks or events may be performed in serial, in parallel, or in some other suitable manner. Tasks or events may be added to or removed from the disclosed example embodiments. The example systems and components described herein may be configured differently than described. For example, elements may be added to, removed from, or rearranged compared to the disclosed example embodiments.

Those of skill in the art will appreciate that information and signals may be represented using any of a variety of different technologies and techniques. For example, data. instructions, commands, information, signals, bits, symbols, and chips that may be referenced throughout the above description may be represented by voltages, currents, electromagnetic waves, magnetic fields or particles, optical fields or particles, or any combination thereof.

The word “exemplary” is used herein to mean “serving as an example, instance, or illustration.” Any aspect described herein as “exemplary” is not necessarily to be construed as preferred or advantageous over other aspects. Likewise, the term “aspects” does not require that all aspects include the discussed feature, advantage or mode of operation.

While the above descriptions contain many specific embodiments of the invention. these should not be construed as limitations on the scope of the invention, but rather as examples of specific embodiments thereof. Accordingly, the scope of the invention should be determined not by the embodiments illustrated, but by the appended claims and their equivalents. Moreover, reference throughout this specification to “one embodiment,” “an embodiment,” or similar language means that a particular feature, structure, or characteristic described in connection with the embodiment is included in at least one embodiment of the present disclosure. Thus, appearances of the phrases “in one embodiment,” “in an embodiment,” and similar language throughout this specification may, but do not necessarily, all refer to the same embodiment, but mean “one or more but not all embodiments” unless expressly specified otherwise.

The terminology used herein is for the purpose of describing particular aspects only and is not intended to be limiting of the aspects. As used herein, the singular forms “a,” “an” and “the” are intended to include the plural forms as well (i.e., one or more), unless the context clearly indicates otherwise. An enumerated listing of items does not imply that any or all of the items are mutually exclusive and/or mutually inclusive, unless expressly specified otherwise. It will be further understood that the terms “comprises,” “comprising.” “includes” “including,” “having,” and variations thereof when used herein mean “including but not limited to” unless expressly specified otherwise. That is, these terms may specify the presence of stated features. integers, steps, operations, elements, or components, but do not preclude the presence or addition of one or more other features, integers, steps, operations, elements, components, or groups thereof. Moreover, it is understood that the word “or” has the same meaning as the Boolean operator “OR,” that is, it encompasses the possibilities of “either” and “both” and is not limited to “exclusive or” (“XOR”), unless expressly stated otherwise. It is also understood that the symbol “/” between two adjacent words has the same meaning as “or” unless expressly stated otherwise. Moreover, phrases such as “connected to,” “coupled to” or “in communication with” are not limited to direct connections unless expressly stated otherwise

Any reference to an element herein using a designation such as “first,” “second,” and so forth does not generally limit the quantity or order of those elements. Rather, these designations may be used herein as a convenient method of distinguishing between two or more elements or instances of an element. Thus, a reference to first and second elements does not mean that only two elements may be used there or that the first element must precede the second element in some manner. Also, unless stated otherwise a set of elements may include one or more elements. In addition, terminology of the form “at least one of a, b, or c” or “a, b, c, or any combination thereof” used in the description or the claims means “a or b or c or any combination of these elements.” For example, this terminology may include a, or b, or c, or a and b, or a and c, or a and b and c, or 2a, or 2b, or 2c, or 2a and b, and so on.

As used herein, the term “determining” encompasses a wide variety of actions. For example, “determining” may include calculating, computing, processing, deriving, investigating, looking up (e.g., looking up in a table, a database or another data structure). ascertaining, and the like. Also, “determining” may include receiving (e.g., receiving information), accessing (e.g., accessing data in a memory), and the like. Also, “determining” may include resolving, selecting, choosing, establishing, and the like.

What is claimed is:

1. A method for connecting an interposer, comprising:
aligning a first array of conductive rings on a flexible substrate of the interposer with ball pads of a ball grid array device;
coupling the first array of conductive rings to the ball pads of the ball grid array device;
aligning a second array of conductive rings on the flexible substrate of the interposer with connectors of a first printed circuit board comprising an array of connectors for coupling to the ball grid array device; and
coupling the second array of conductive rings to the array of connectors of the first printed circuit board.

2. The method for connecting an interposer of claim 1, further comprising:
removing, before aligning the first array of conductive rings in the flexible substrate with the ball pads on the ball grid array device, the ball grid array device from a second printed circuit board;
removing, after removing the ball grid array device from the second printed circuit board and before aligning the first array of conductive rings in the flexible substrate with the ball pads on the ball grid array device, one or more of a plurality of solder balls on the ball pads; and
testing, responsive to the second array of conductive rings being coupled to the printed circuit board, the ball grid array device.

3. The method for connecting an interposer of claim 2:
wherein the removing the ball grid array device from the second printed circuit board comprises removing the ball grid array device from the second printed circuit board without using a machine that generates evenly dispersed heat; and
wherein the coupling the first array of conductive rings to the ball pads of the ball grid array device comprises coupling the first array of conductive rings to the ball pads of the ball grid array device without using a machine that generates evenly dispersed heat.

4. The method for connecting an interposer of claim 1, wherein the coupling the first array of conductive rings to the ball pads of the ball grid array device comprises coupling the first array of conductive rings to the ball pads of the ball grid array device using a soldering iron.

5. The method for connecting an interposer of claim 1:
wherein the coupling the first array of conductive rings to the ball pads of the ball grid array device further comprises:
applying solder paste and heat to at least one conductive ring in the first array of conductive rings to electrically bond the conductive rings to respective ball pad of the ball grid array device; and
wherein the coupling the second array of conductive rings to the connectors of the printed circuit board further comprises:
applying solder paste and heat to at least one conductive ring in the second array of conductive rings to electrically bond the second array of conductive rings to respective connectors of the first printed circuit board.

6. The method for connecting an interposer of claim 1, wherein a first pattern of the first array of conductive rings on the flexible substrate and a second pattern of the second array of conductive rings on the flexible substrate are substantially the same.

7. The method for connecting an interposer of claim 1, wherein each conductive ring in the first array of conductive rings and each conductive ring in the second array of conductive rings comprises:
a conductive material coated on walls formed by a bole through the flexible substrate, wherein the conductive material comprises a cylindrical hole and thereby forms the conductive ring at a surface of the flexible substrate.

8. The method for connecting an interposer of claim 1:
wherein coupling the first array of conductive rings to the ball pads of the ball grid array device further comprises attaching the ball grid array device to the flexible substrate using a solder paste; and
wherein coupling the second array of conductive rings to the connectors of the printed circuit board further comprises attaching the flexible substrate to the printed circuit board using the solder paste.

9. An interposer assembly, comprising:
a flexible substrate;
a first array of conductive rings formed in a first pattern on the flexible substrate, wherein the first array of conductive rings is attached to an array of ball pads of a ball grid array device such that at least one conductive ring of the first array of conductive rings is attached to one ball pad of the array of ball pads;
a second array of conductive rings formed in a second pattern on the flexible substrate; and
a plurality of conductive traces connecting conductive rings of the first array to conductive rings of the second array.

10. The interposer assembly of claim 9, wherein the interposer does not include a planar conductive pad that extends along a surface of the interposer and is configured to couple to a connector of a ball grid array device.

11. The interposer assembly of claim 9, wherein the array of ball pads does not include solder balls.

12. The interposer assembly of claim 9, wherein the ball grid array device is a solid-state device comprising a non-volatile memory.

13. The interposer assembly of claim 9:
wherein the first pattern on the flexible substrate and the second pattern on the flexible substrate are substantially the same; and
wherein the first pattern on the flexible substrate is selected to match a ball pattern of the ball grid array device.

14. The interposer assembly of claim 9:
wherein the second array of conductive rings is configured to couple to connectors of a printed circuit board; and
wherein the second array of conductive rings formed in the second pattern on the flexible substrate is selected to match a connection pattern of the connectors of the printed circuit board.

15. The interposer assembly of claim 9, wherein each conductive ring in the first array of conductive rings and each conductive ring in the second array of conductive rings comprises:
a conductive material coated on walls formed by a hole through the flexible substrate, wherein the conductive material comprises a cylindrical hole and thereby forms the conductive ring at a surface of the flexible substrate.

16. The interposer assembly of claim 15, wherein each cylindrical hole of the conductive material is configured to receive and facilitate spread of solder paste.

17. The interposer assembly of claim 9, wherein each conductive ring of the first array of conductive rings is attached to a corresponding ball pad of the array of ball pads of the ball grid array.

18. The interposer assembly of claim 17, wherein a center of each conductive ring of the first array of conductive rings is substantially aligned with a center of the corresponding ball pad of the array of ball pads of the ball grid array.

19. A method for connecting an interposer comprising a flexible substrate comprising first and second arrays of conductive rings, the method comprising:
aligning the second array of conductive rings on the flexible substrate of the interposer with connectors of a first printed circuit board comprising an array of connectors for coupling to a ball grid array device;
coupling the second array of conductive rings to the array of connectors of the first printed circuit board;
aligning the first array of conductive rings on the flexible substrate of the interposer with ball pads of a ball grid array device; and
coupling the first array of conductive rings to the ball pads of the ball grid array device.

20. The method of claim 19, further comprising:
removing, before aligning the first array of conductive rings on the flexible substrate of the interposer with ball pads on the ball grid array device, the ball grid array device from a second printed circuit board;
removing, after removing the ball grid array device from the second printed circuit board and before aligning the first array of conductive rings in the flexible substrate with the ball pads on the ball grid array device, one or more of a plurality of solder balls on the ball pads; and
testing, responsive to the first array of conductive rings being coupled to the ball grid array device, the ball grid array device.

21. The method of claim 20:
wherein the removing the ball grid array device from the second printed circuit board comprises removing the ball grid array device from the second printed circuit board without using a machine that generates evenly dispersed heat; and
wherein the coupling the first array of conductive rings to the ball pads of the ball grid array device comprises coupling the first array of conductive rings to the ball pads of the ball grid array device without using a machine that generates evenly dispersed heat.
